(19) United States
(12) Patent Application Publication
(10) Pub. No.: US 2025/0167008 A1
(43) Pub. Date: May 22, 2025

(54) GAS DELIVERY SYSTEM FOR A THERMAL PROCESSING APPARATUS

(71) Applicants: Beijing E-Town Semiconductor Technology Co., Ltd., Beijing (CN); Mattson Technology, Inc., Fremont, CA (US)

(72) Inventors: Matthias Bauer, Dornstadt (DE); Rolf Bremensdorfer, Bibertal (DE); Alexandr Cosceev, Lonsee (DE); Silke Hamm, Laupheim (DE); Dieter Hezler, Lonsee (DE); Eric Agha, Blaustein (DE); Christian Pfahler, Ulm (DE); Kartik Shah, Saratoga, CA (US); Alex Wansidler, Blaustein (DE)

(21) Appl. No.: 18/952,428

(22) Filed: Nov. 19, 2024

Related U.S. Application Data
(60) Provisional application No. 63/601,441, filed on Nov. 21, 2023.

(51) Int. Cl. H01L 21/67

(52) U.S. Cl. CPC H01L 21/67017; H01L 21/67109; H01L 21/67115; H01L 21/67248

(57) ABSTRACT

A gas delivery system for a thermal processing apparatus is disclosed. The gas delivery system includes a cover plate and a distribution plate extending axially between a first surface and a second surface, the first and second surfaces extending perpendicular to the axial direction, the distribution plate having a distribution area comprising plurality of holes extending axially therethrough. The gas delivery system includes one or more collars coupled axially between the cover plate and the distribution plate, the collar, the cover plate, and the distribution plate together defining an interior chamber and a gas supply coupled to the collar to provide process gas from a gas source to the interior chamber. The total area of the holes is from about 0.1% to about 0.9% of a total area of the distribution area on the distribution plate. Thermal processing apparatuses and methods of use are also provided.

### CROSS-REFERENCE TO RELATED APPLICATION

This application claims the benefit of U.S. Provisional Application No. 63/601,441, filed Nov. 21, 2023, the entirety of which is incorporated by reference herein.

### FIELD

The present disclosure relates generally to thermal processing systems, and more particularly a rapid thermal processing systems having a gas delivery system.

### BACKGROUND

A thermal processing chamber as used herein refers to a system that heats workpieces, such as semiconductor workpieces (e.g., semiconductor wafers). Such systems can include a support plate for supporting one or more workpieces and an energy source for heating the workpieces, such as heating lamps, lasers, or other heat sources. During heat treatment, the workpiece(s) can be heated under controlled conditions according to a processing regime.

Many thermal treatment processes require a workpiece to be heated over a range of temperatures so that various chemical and physical transformations can take place as the workpiece is fabricated into a device(s). During rapid thermal processing, for instance, workpieces can be heated by an array of lamps through the support plate to temperatures from about 300° C. to about 1,200° C. over time durations that are typically less than a few minutes.

### SUMMARY

Aspects and advantages of embodiments of the present disclosure will be set forth in part in the following description, or may be learned from the description, or may be learned through practice of the embodiments.

In one aspect, a gas delivery system for a thermal processing apparatus is provided. The gas delivery system includes a cover plate, a distribution plate, one or more collars, and a gas supply. The distribution plate extends axially between a first surface and a second surface, the first and second surfaces extending perpendicular to the axial direction, the distribution plate having a distribution area comprising plurality of holes extending axially therethrough. One or more collars are coupled axially between the cover plate and the distribution plate. The collar, cover plate, and the distribution plate define an interior chamber. The gas supply is coupled to the collar to provide process gas from a gas source to the interior chamber. A total area of the holes in the distribution plate is from about 0.1% to about 0.9% of the total area of the distribution area on the distribution plate.

In another aspect, a thermal processing system for performing rapid thermal processing of semiconductor workpieces is provided. The system includes a processing chamber and a workpiece support configured to support a workpiece within the processing chamber. A heat source is provided to heat the workpiece. The system includes a temperature measurement system configured to generate data indicative of a temperature of the workpiece. A gas delivery system is provided that is configured to flow a process gas over the workpiece supported on the workpiece support. The gas delivery system includes a cover plate and a distribution plate extending axially between a first surface and a second surface, the first and second surfaces extending perpendicular to the axial direction, the distribution plate having a distribution area comprising plurality of holes extending axially therethrough. The gas delivery system includes one or more one or more collars coupled axially between the cover plate and the distribution plate, the collar, the cover plate, and the distribution plate together defining an interior chamber. The gas delivery system includes a gas supply coupled to the collar to provide process gas from a gas source to the interior chamber. The total area of the holes is from about 0.1% to about 0.9% of a total area of the distribution area on the distribution plate.

Other example aspects provide a method for performing a thermal process on a workpiece. The method includes controlling, by one or more controllers, a heat source to begin heating a workpiece supported on a workpiece support in a processing chamber; optionally, receiving, by the one or more control devices, data from a temperature measurement system indicative of a temperature of the workpiece; optionally, monitoring, by the one or more control devices, the temperature of the workpiece relative to a temperature setpoint; and controlling, by the one or more controllers, a gas delivery system to supply a process gas to the processing chamber. The gas delivery system includes a cover plate and a distribution plate extending axially between a first surface and a second surface, the first and second surfaces extending perpendicular to the axial direction, the distribution plate having a distribution area comprising plurality of holes extending axially therethrough. The gas delivery system includes one or more one or more collars coupled axially between the cover plate and the distribution plate, the collar, the cover plate, and the distribution plate together defining an interior chamber. The gas delivery system includes a gas supply coupled to the collar to provide process gas from a gas source to the interior chamber. The total area of the holes is from about 0.1% to about 0.9% of a total area of the distribution area on the distribution plate. The method includes removing the workpiece from the processing chamber after the thermal process is complete.

Other example aspects of the present disclosure are directed to systems, methods, devices, and processes for performing rapid thermal processing of semiconductor workpieces.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a rapid thermal processing system according to example embodiments of the present disclosure;

FIG. 2 depicts a cross-sectional view of an example gas delivery system of a thermal processing system according to example embodiments of the present disclosure;

FIG. 3 depicts an exploded, perspective view of an example gas delivery system of a thermal processing system according to example embodiments of the present disclosure;

FIG. 4 depicts a partial, perspective view of an example gas delivery system of a thermal processing system, particularly illustrating a gas supply of the gas delivery system according to example embodiments of the present disclosure;

FIG. 5 depicts a partial, perspective view of an example gas delivery system of a thermal processing system, particularly illustrating a gas supply of the gas delivery system according to example embodiments of the present disclosure;

FIG. 6 depicts a partial, perspective view of an example gas delivery system of a thermal processing system, particularly illustrating a gas supply of the gas delivery system according to example embodiments of the present disclosure;

FIG. 7 depicts a partial, perspective view of an example gas delivery system of a thermal processing system, particularly illustrating a gas supply of the gas delivery system according to example embodiments of the present disclosure;

FIG. 8 depicts a partial, perspective view of an example gas delivery system of a thermal processing system, particularly illustrating a gas supply of the gas delivery system according to example embodiments of the present disclosure;

FIG. 9 depicts a partial, perspective view of an example gas delivery system of a thermal processing system, particularly illustrating a gas supply of the gas delivery system according to example embodiments of the present disclosure;

FIG. 10 depicts a partial, schematic view of an example gas delivery system of a thermal processing system, particularly illustrating a gas supply of the gas delivery system according to example embodiments of the present disclosure;

FIG. 11 depicts a partial, perspective view of an example gas delivery system of a thermal processing system, particularly illustrating a gas supply of the gas delivery system according to example embodiments of the present disclosure;

FIG. 12 depicts a partial, schematic view of an example gas delivery system of a thermal processing system, particularly illustrating a gas supply of the gas delivery system according to example embodiments of the present disclosure;

FIG. 13 depicts a partial, schematic view of an example gas delivery system of a thermal processing system, particularly illustrating a gas supply of the gas delivery system according to example embodiments of the present disclosure;

FIG. 14 depicts a partial, top-down schematic view of an example gas delivery system of a thermal processing system, particularly illustrating an example embodiment utilizing two collars according to example embodiments of the present disclosure;

FIG. 15 depicts a partial, cross-section schematic view of an example gas delivery system of a thermal processing system, particularly illustrating an example embodiment utilizing two collars according to example embodiments of the present disclosure;

FIG. 16 depicts a top-down view of a distribution plate of an example gas delivery system of a thermal processing system according to example embodiments of the present disclosure;

FIG. 17 depicts a top-down view of a distribution plate of an example gas delivery system of a thermal processing system according to example embodiments of the present disclosure;

FIG. 18 depicts a top-down view of a distribution plate of an example gas delivery system of a thermal processing system according to example embodiments of the present disclosure;

FIG. 19 depicts a top-down view of a distribution plate of an example gas delivery system of a thermal processing system according to example embodiments of the present disclosure;

FIG. 20 depicts a top-down view of a distribution plate of an example gas delivery system of a thermal processing system according to example embodiments of the present disclosure;

FIG. 21 depicts a perspective view of a mechanical fastener of an example gas delivery system of a thermal processing system according to example embodiments of the present disclosure;

FIG. 22 depicts a bottom, perspective view of an example gas delivery system of a thermal processing system, particularly illustrating a mechanical fastener coupled to a cover plate of the gas delivery system according to example embodiments of the present disclosure;

FIG. 23 depicts a partial, perspective view of an example gas delivery system of a thermal processing system, particularly illustrating flexible flanges of a cover plate of the gas delivery system according to example embodiments of the present disclosure; and

FIG. 24 depicts a flow diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to thermal processing systems, such as rapid thermal processing (RTP) systems, for workpieces, such as semiconductor workpieces (e.g., silicon workpieces). In particular, example aspects of the present disclose are directed to more tightly controlling gas delivery into the processing chamber or processing space during a thermal process (e.g., a thermal oxidation process). Thermal oxidation processes can be used to deposit a thin layer of oxide on a workpiece. Process gas flow in and within the processing chamber during deposition can affect the growth of the oxide layer on the wafer and, thus, can significantly affect the uniformity of the deposited layer on the workpiece.

In fact, many RTP systems are only capable of providing gas through a sidewall of the chamber and thus the gas flows in a direction that is parallel to the workpiece. As such, portions of the workpiece exposed first to the gas can experience accelerated gas flow, which can cause a thicker layer of material to form on the workpiece in a faster manner as compared to other areas of the workpiece.

According to example aspects of the present disclosure, a gas delivery system can be disposed proximate a workpiece (e.g., a semiconductor material or wafer) configured to be heated by light emitted by one or more heat sources (e.g., lamp heat source(s), laser(s), or any other suitable light source). The gas delivery system can be configured to supply a flow of process gas over the workpiece in a top-down manner to increase processing efficiencies and improve process uniformity of the wafer during deposition processes.

For instance, the gas delivery system can include a distribution plate positioned axially adjacent the workpiece support, where the distribution plate can have a surface parallel to the workpiece support and perpendicular to the axial direction and a plurality of holes extending axially therethrough. The gas delivery system may further include a cover plate positioned axially adjacent the distribution plate, opposite the workpiece support, and a collar coupled axially between the distribution plate and the cover plate, such that the collar, the distribution plate, and the cover plate together can define an interior chamber. A gas supply of process gas can be coupled to the collar to provide the process gas from a gas source to the interior chamber. The process gas provided to the interior chamber can flow out of the interior chamber through the plurality of holes in the distribution plate and across the workpiece surface. The plurality of holes in the distribution plate includes a total surface area of from about 0.1% to about 0.9% of the total surface area of a distribution area located on the distribution plate.

Moreover, in some aspects of the present disclosure, the gas supply may be configured to improve the distribution of the gas across the distribution plate and thus, across the workpiece. For instance, in some aspects, the gas supply may have an inlet plate coupled to and extending along the azimuthal direction between first and second ends of the collar spaced apart by a gap distance, where the inlet plate may include a plurality of inlet openings spaced apart along the azimuthal direction. In some aspects, the gas supply may further include a plurality of inlet tubes, where each of the plurality of inlet tubes connects a respective one of the plurality of inlet openings to the gas source. In other embodiments, the gas supply can include a gas supply device that is configured to provide process gas from the gas supply to the interior space. The gas supply device can include a housing configured to reduce the pressure of the flow of process gas, increase the flow rate of the process gas, or reduce turbulence of the process gas prior to entering the interior space.

Further, in some aspects of the present disclosure, the cover plate may be clamped to the distribution plate to seal or render the interior chamber of the gas delivery system gas tight. For instance, in one aspect, the cover plate can include a plurality of flexible flanges, where each of the plurality of flexible flanges may extend along a respective azimuthal section and have an opening for receiving a respective mechanical fastener for coupling the cover plate, the collar, and the distribution plate together. The flexible flanges may be bent or displaced towards the distribution plate during a clamping process to allow the mechanical fastener to fasten the cover plate to the distribution plate, clamping the collar therebetween.

Thus, technical benefits of the present disclosure include the ability to tightly control process gas flow during thermal processing of the workpiece. Further, utilization of the gas supply system as disclosed is capable of providing top down flow of process gas over and across the workpiece during processing, which can result in improved uniformity during workpiece processing.

Aspects of the present disclosure are discussed with reference to a “workpiece” “wafer” or semiconductor wafer for purposes of illustration and discussion. Those of ordinary skill in the art, using the disclosures provided herein, will understand that the example aspects of the present disclosure can be used in association with any semiconductor substrate or other suitable substrate. In addition, the use of the term “about” in conjunction with a numerical value is intended to refer to within ten percent (10%) of the stated numerical value.

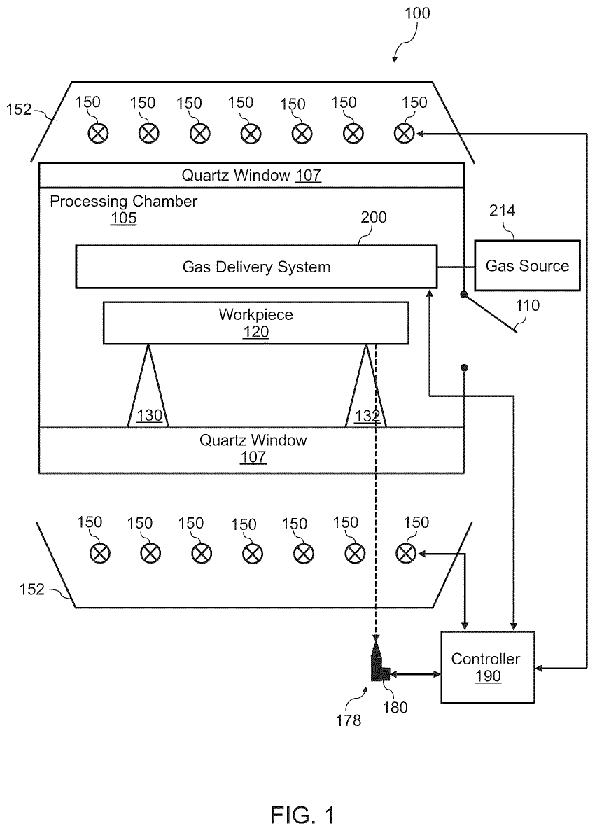

Referring now to the figures, FIG. 1 depicts a thermal processing system 100 according to example embodiments of the present disclosure. As shown, the thermal processing system 100 can include a processing chamber 105. In some implementations, the processing chamber 105 can be defined, at least in part, by quartz windows 107 of the thermal processing system 100. For instance, one of the quartz windows 107 may at least partially define a ceiling of the processing chamber 105 and another of the quartz windows 107 may at least partially define a floor or bottom surface of the processing chamber 105. In some implementations, the quartz windows 107 can be doped with hydroxide OH. It should be appreciated that the one or more surfaces defining the processing chamber 105 can be formed from any suitable material. For instance, in some implementations, the one or more surfaces defining the processing chamber 105 can be formed from quartz.

As shown, the thermal processing system 100 can include a door 110 movable between an open position (FIG. 1) and a closed position (not shown) to permit selective access to the processing chamber 105. For instance, the door 110 can be moved to the open position to allow a workpiece 120 to be positioned within the processing chamber 105. In some implementations, the workpiece 120 can be supported, at least in part, by support pins 130, 132 of the lower one of the quartz windows 107. In this manner, heat associated with emitting light onto the lower quartz window 170 can be transferred to the workpiece 120 via the support pins 130, 132. In some embodiments, the workpiece 120 may be rotatable within the processing chamber 105, for instance, during a thermal treatment process. For example, the support pins 130, 132 may be configured to rotate relative to the lower one of quartz windows 107. Furthermore, the door 110 can be moved to the closed position once the workpiece 120 is disposed on the support pins 130, 132 of the lower quartz window 107. In some implementations, the processing chamber 105 can be sealed off from an external environment when the door 110 is in the closed position.

The thermal processing system 100 can include one or more heat sources 150 disposed outside of the processing chamber 105. For instance, the heat sources 150 may be positioned above the processing chamber 105, below the processing chamber 105, or both above and below the processing chamber 105. The one or more heat sources 150 can be configured to emit light towards the workpiece 120 during a thermal treatment process, such as a rapid thermal treatment, or a spike anneal process. More particularly, the heat sources 150 positioned above the processing chamber 105 may be configured to emit light towards an upper surface or side of the workpiece 120 and the heat sources 150 positioned below the processing chamber 105 may be configured to emit light towards a lower surface or side of the workpiece 120 during a thermal treatment process. The light emitted from the one or more heat sources 150 can raise a temperature of the workpiece 120. In some implementations, the one or more heat sources 150 can increase the temperature of the workpiece 120 by greater than about 500° C. within a predetermined amount of time (e.g., less than 2 seconds).

It should be appreciated that the one or more heat sources 150 can include any suitable type of heat source configured to emit light. For instance, in some implementations, the one or more heat sources 150 can include one or more heat lamps (e.g., linear lamps). In alternative implementations, the one or more heat sources 150 can include one or more lasers configured to emit a laser beam onto the workpiece 120. It should further be appreciated that the heat sources 150 positioned above the processing chamber 105 may be controlled separately from the heat sources 150 positioned below the processing chamber 105 or may be controlled together for performing a thermal treatment process.

In some implementations, the thermal processing system 100 can include one or more reflectors 152 positioned such that the light emitted from the one or more heat sources 150 is directed to or towards the processing chamber 105. More specifically, the reflectors 152 can direct the light emitted from the one or more heat sources 150 to or towards the respective quartz window 107 such that the light can pass through the respective quartz window 107 and into the processing chamber 105. It should be appreciated that at least a portion of the light entering the processing chamber 105 via the quartz window(s) 107 can be emitted onto the workpiece 120. In this manner, the light emitted from the one or more heat sources 150 can, as discussed above, raise the temperature of the workpiece 120 during a thermal treatment process, such as a rapid thermal treatment process (e.g., spike anneal treatment).

In one implementation, the thermal processing system 100 can include a temperature measurement system 178 configured to generate and communicate data indicative of a temperature of the workpiece 120. The temperature measurement system 178 may include one or more temperature sensors 180. The temperature sensor(s) 180 may comprise pyrometer(s), thermocouple(s), thermistor(s), or any other suitable temperature sensor or combination of temperature sensors. The temperature sensor(s) 180 may be positioned within the processing chamber 105 or may be positioned exterior to the processing chamber 105, depending on the type of sensor. For example, if the temperature sensor(s) 180 is a pyrometer, the pyrometer does not need to contact the workpiece 120, and thus, may be positioned exterior to the chamber 105. However, if the temperature sensor(s) 180 is a thermocouple, the thermocouple must be in contact with the workpiece 120, and thus, may be positioned interior to the chamber 105. Further, the temperature sensor(s) 180 may be communicatively coupled to a controller 190, by a wired connection, a wireless connection, or both, such that the data generated by the sensor(s) 180 indicative of the temperature of the workpiece 120 may be provided to the controller 190.

According to example aspects of the present disclosure, the thermal processing system 100 includes a gas delivery system 200, as will be described below in greater detail, configured to selectively flow process gas from a gas source 214 across the workpiece 120 during a thermal process. The controller 190 can control the operation of the heat source(s) 150 and the gas delivery system 200 (e.g., a flow rate of process gas across the workpiece 120) during a thermal process. For instance, the controller 190 can control the operation of the gas delivery system 200 to modify uniformity of processing of the workpiece 120. Additionally, the controller 190 can control the rotation of the workpiece 120. For instance, the controller 190 can control the workpiece support (e.g., support pin(s)) such that the workpiece 120 is rotated during a thermal process, such as while the gas delivery system 200 is operated.

In some embodiments, the controller 190 (e.g., a computer, microcontroller(s), other control device(s), etc.) can include one or more processors and one or more memory devices. The one or more memory devices can store computer-readable instructions that when executed by the one or more processors cause the one or more processors to perform operations, such as turning on or turning off the heat source(s) 150, controlling an operation of the gas delivery system 200 during the thermal process, or other suitable operation as will be described below.

In some implementations, process gas is provided by a gas delivery system 200. In this manner, a process gas(es) provided from a process gas source 214 can be provided in the processing chamber 105. The process gas can include an inert gas that does not react with the workpiece 120. Alternatively, the process gas can include a reactive gas that reacts with workpiece 120 to deposit a layer of material on the surface of the workpiece 120. For instance, in some implementations, the process gas can include ammonium NH₃ gas. It should be appreciated, however, that the process gas can include any suitable reactive gas. For instance, in alternative implementations, the reactive gas can include H₂ gas.

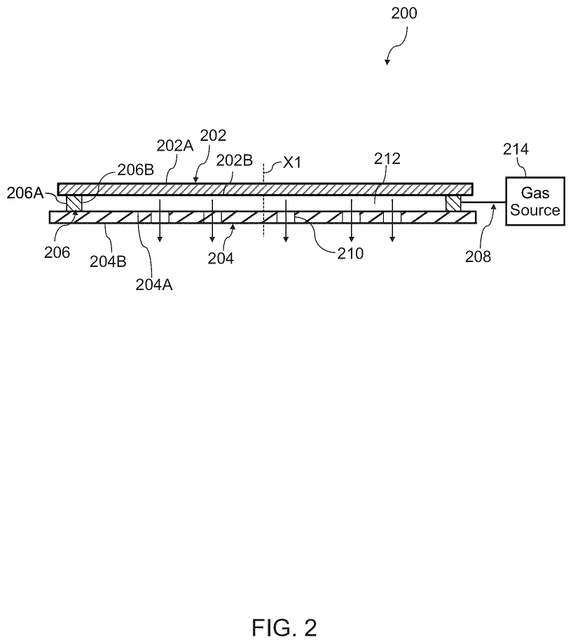

Turning now to FIG. 2, the gas delivery system 200 comprises a cover plate 202, a distribution plate 204, a collar 206, and a gas supply 208, each of which may be comprised of quartz. The cover plate 202 extends along an axial direction X1 between an upper surface 202A and a lower surface 202B. The cover plate 202 is continuous such that it has no openings extending axially therethrough through which process gas may flow. The distribution plate 204 similarly extends along the axial direction X1 between an upper surface 204A and a lower surface 204B, where the lower surface 204B is positioned axially closer to a workpiece (e.g., workpiece 120 in FIG. 1) supported in the processing chamber 105 (FIG. 1) than the upper surface 204A. At least the lower surface 204B of the distribution plate 204 extends perpendicular to the axial direction X1 such that it is generally parallel to the workpiece surface (FIG. 1) or a support plane of the workpiece support 130, 132 (FIG. 1). Unlike the cover plate 202, the distribution plate 204 has a plurality of holes 210 extending therethrough, as will be described below in greater detail. In one embodiment, the holes 210 extend along the axial direction X1. However, in other embodiments, the holes 210 may instead extend at an angle relative to the axial direction X1. The cover plate 202 is generally positioned axially adjacent to the distribution plate 204, opposite the workpiece support 130, 132 (FIG. 1).

The collar 206 extends radially between an outer side 206A and an inner side 206B. The collar 206 is positioned axially between the lower surface 202B of the cover plate 202 and the upper surface 204A of the distribution plate 204 such that an interior chamber 212 is defined between the radially inner side 206B of the collar 206, the lower surface 202B of the cover plate 202, and the upper surface 204A of the distribution plate 204. The gas supply 208 is configured to selectively supply the interior chamber 212 process gas from the gas source 214. The process gas supplied to the interior chamber 212 may then flow from the interior chamber 212 via the holes 210 and across a workpiece supported below the gas delivery system 200.

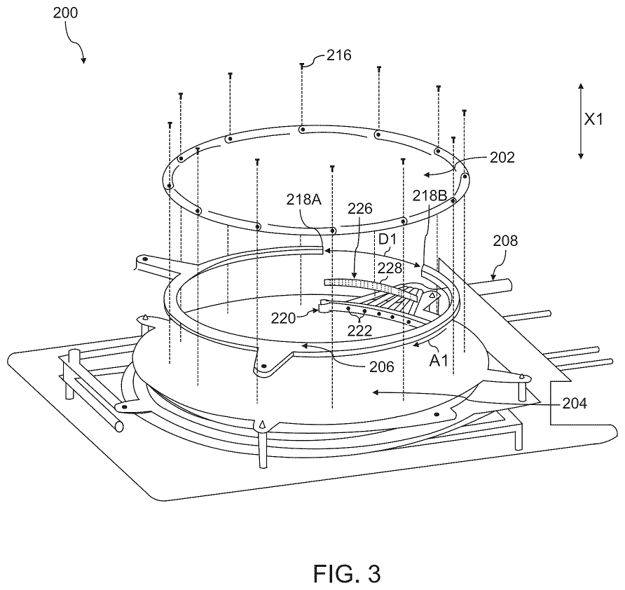

As particularly shown in the exploded view of the gas delivery system 200 in FIG. 3, the cover plate 202 is able to be directly coupled to the distribution plate 204 by a plurality of mechanical fasteners 216 as will be described below in greater detail. Further, the collar 206 has a gap extending along an azimuthal direction A1 between a first azimuthal end 218A and a second azimuthal end 218B. The first and second azimuthal ends 218A, 218B are spaced apart by a gap distance D1 along the azimuthal direction A1. The gas supply 208 comprises an inlet plate 220 that is able to be installed or coupled between the first and second azimuthal ends 218A, 218B of the collar 206. When installed, the inlet plate 220 extends along the azimuthal direction A1 along the entire gap distance D1 to define at least a portion of the interior chamber 212. However, it should be appreciated that the inlet plate 220 may instead extend linearly between the first and second ends 218A, 218B of the collar. In one aspect, the inlet plate 220 includes a plurality of inlet openings 222 spaced apart along the azimuthal direction A1 through which process gas is supplied into the interior chamber 212, as will be described in greater detail below. In some embodiments, the gas supply 208 further includes a baffle plate 226. The baffle plate 226 is spaced radially inwardly from the inlet plate 220 and extends along at least a portion of the gap distance D1. For instance, in some aspects, the baffle plate 226 is coupled to a radially inward portion of the inlet plate 220 to define at least a portion of the interior chamber 212. In some aspects, the baffle plate 226 includes a plurality of diffusing openings 228 through which process gas supplied through the inlet openings 222 must travel before being received in the interior chamber 212, as will be described in greater detail below.

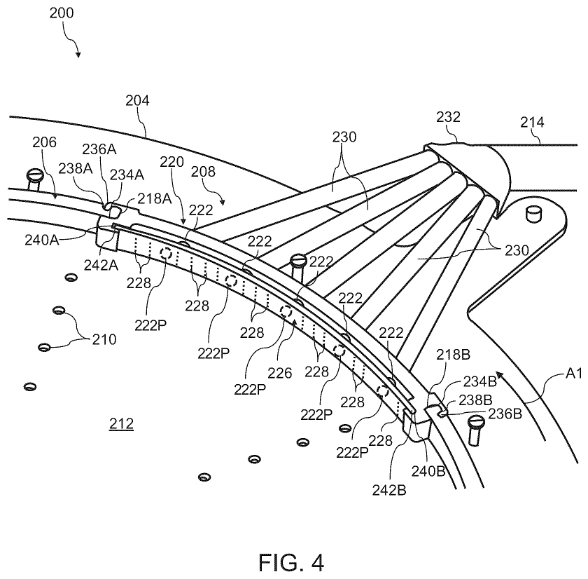

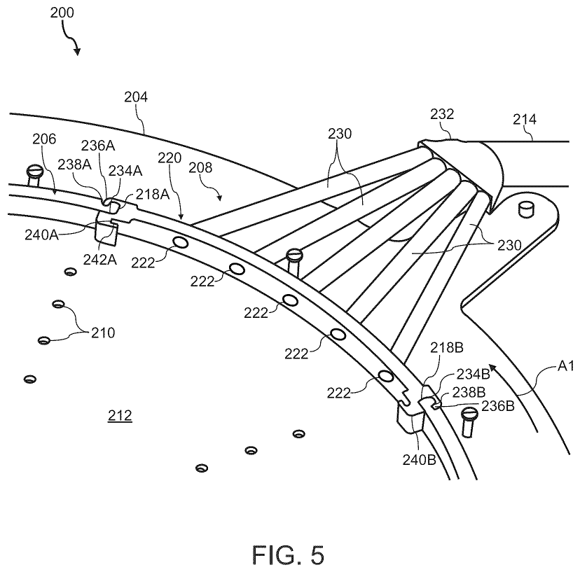

Turning now to FIGS. 4-5, the gas supply 208 is configured to evenly disperse process gas across the distribution plate 204. For instance, as discussed above, the inlet openings 222 of the inlet plate 220 are spaced apart along the azimuthal direction A1. For instance, in some embodiments, the inlet openings 222 may be spaced evenly apart along the azimuthal direction A1. Further, the inlet openings 222 may, in some embodiments, have the same cross-sectional area. Each of the inlet openings 222 is, in turn, coupled via a respective inlet tube 230 to the process gas source 214. More particularly, each inlet tube 230 is connected at its first end to a respective one of the inlet openings 222 and at its second end to an adapter 232. The adapter 232 is configured to connect the second end of inlet tube 230 to the gas source 214. However, it should be appreciated that, in some embodiments, each inlet tube 230 may be separately coupled to the gas source 214 (e.g., by respective adapters or couplings). The inlet openings 222 and tubes 230 divide a flow of process gas from the gas source 214 such that the gas enters the interior chamber at multiple azimuthal positions. In some embodiments, the inlet openings 222 and the tubes 230 evenly divide the flow of process gas from the gas source 214. However, in some embodiments, different pairings of the inlet openings 222 and the tubes 230 may provide a different proportion of the flow of process gas from the gas source 214 to the interior chamber. While five inlet openings 222 and tubes 230 are illustrated, the gas supply 208 may include any other suitable number, such as four or fewer, or such as six or more.

Moreover, in some embodiments, the baffle plate 226 is positioned radially inwardly of the inlet plate 220 and includes its own diffusing openings 228, as discussed above. Notably, FIG. 5 illustrates an example gas supply 208 that does not include the baffle plate 226. In some aspects, the diffusing openings 228 are smaller in cross-section and more numerous than the inlet openings 222 such that the gas flowed through the inlet openings 222 is further divided by the diffusing openings 228. In one aspect, the diffusing openings 228 may be positioned at different azimuthal positions from the inlet openings 222. For instance, projections 222P of the inlet openings 222 in FIG. 4 illustrate the respective azimuthal positions of the inlet openings 222 relative to the diffusing openings 228. The projections 222P of the inlet openings 222 are spaced apart along the azimuthal direction A1 from the diffusing openings 228. Further, the projections 222P of the inlet openings 222 alternate with the diffusing openings 228 along the azimuthal direction A1 such that at least one of the diffusing openings 228 is positioned between each pair of neighboring projections 222P along the azimuthal direction A1. By offsetting the inlet openings 222 and the diffusing openings 228 along the azimuthal direction A1, more turbulent flow is generated between the inlet plate 220 and the baffle plate 226 which provides more even distribution of the process gas through the diffusing openings 228.

As further shown in FIGS. 4-5, the inlet plate 220 and the collar 206, in one aspect, have locking features that couple together to form a slip-tight seal. More particularly, the inlet plate 220 has a first channel 234A for receiving the first azimuthal end 218A of the collar 206 and a similar, second channel 234B for receiving the second azimuthal end 218B of the collar 206. The inlet plate 220, in one aspect, further includes a first lip or protruding portion 236A, which is receivable within a first recess 238A formed in the collar 206 proximate the first azimuthal end 218A, and a similar, second lip or protruding portion 236B, which is receivable within a second recess 238B formed in the collar 206 proximate the second azimuthal end 218B. Such locking features 234, 236, 238 form an air-tight seal such that when the cover plate 202 is coupled to the distribution plate 204 with the collar 206 and inlet plate 220 therebetween, process gas may only enter the interior chamber 212 through the inlet plate 220 and exit the interior chamber 212 through the holes 210 in the distribution plate 204.

Additionally, in one embodiment, the baffle plate 226 is configured to be coupled to the inlet plate 220 as indicated above and shown in FIG. 4. For instance, the inlet plate 220 includes a first channel 240A for receiving a first azimuthal end 242A of the baffle plate 226 and a similar, second channel 240B for receiving a second azimuthal end 242B of the baffle plate 226. Such channels 240A, 240B may form an air-tight seal with the baffle plate 226 when the cover plate 202 is coupled to the distribution plate 204 with the collar 206, inlet plate 220, and baffle plate 226 therebetween such that process gas may only enter the interior chamber 212 through the diffusing openings 228 and exit the interior chamber 212 through the holes 210 in the distribution plate 204.

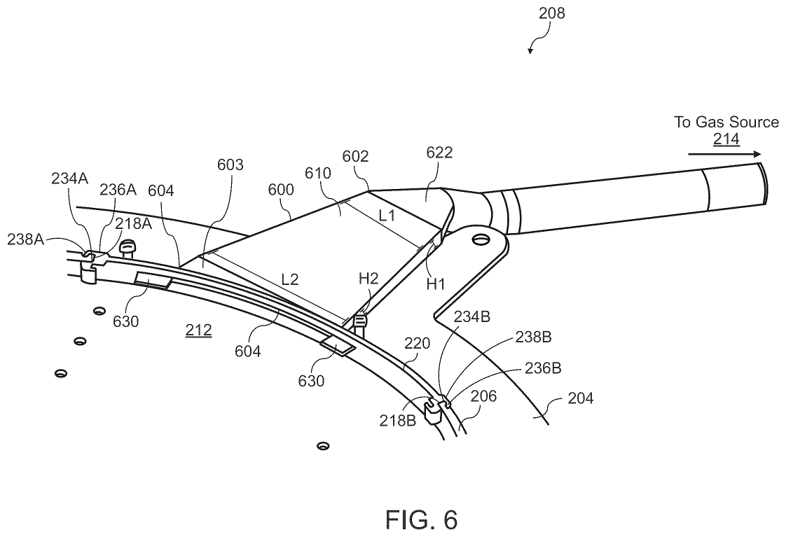

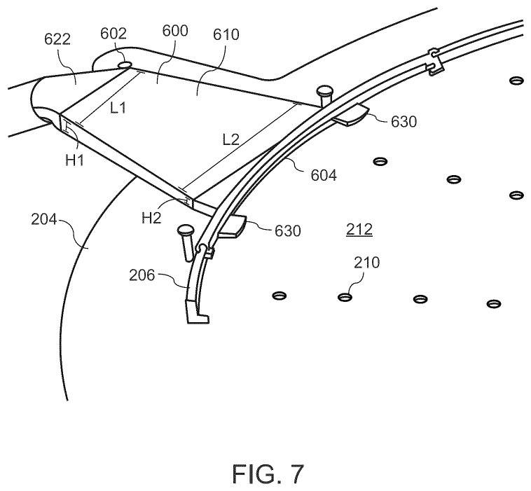

Referring to FIGS. 6-7, another example embodiment of a gas supply 208 including a gas flow device 600 and inlet plate 220 configured to evenly disperse process gas across the distribution plate 204. For instance, the gas flow device 600 is coupled at a first end 602 to the gas source 214 and at a second end 603 to the inlet plate 220. The inlet plate includes a slot 604 extending in the azimuthal direction. Process gas provided by the gas source 214 enters the interior chamber 212 only through the slot 604. Notably, in such an embodiment, no additional distribution plate is required. The gas flow device 600 is not tubular in nature and instead is a housing 610 having generally a top, bottom and sidewalls. The housing 610 can have a first length L1 generally along the first end 602 that is less than a second length L2 of the housing 610 disposed along the second end 603 of the gas flow device 600. Further, the housing 610 can have a first height H1 disposed about the first end 602 that is greater than a second height H₂ of the housing 610 disposed along the second end 603 of the housing 610. In such embodiments, process gas entering the gas flow device 600 is dispersed within an interior of the housing 610 and can be more evenly dispersed within the housing 610 prior to exiting the housing 610 via the slot 604. In this particular embodiment, the adapter 622 is configured to deliver process gas into the housing 610 of the gas flow device 600 in a direction that is parallel to the top and bottom of the housing 610. Additional adapters can be disposed between the first end 602 of the gas flow device 600 and the gas source 214 as needed (not shown). Such dispersion within the housing can ensure more uniformity of gas flow distribution and modify gas flow, pressure, or turbulence in the process gas provided by the gas source 214.

The inlet plate 220 and collar 206, in one aspect, have locking features that couple together to form a slip-tight seal. More particularly, the inlet plate 220 has a first channel 234A for receiving the first azimuthal end 218A of the collar 206 and a similar, second channel 234B for receiving the second azimuthal end 218B of the collar 206. The inlet plate 220, in one aspect, further includes a first lip or protruding portion 236A, which is receivable within a first recess 238A formed in the collar 206 proximate the first azimuthal end 218A, and a similar, second lip or protruding portion 236B, which is receivable within a second recess 238B formed in the collar 206 proximate the second azimuthal end 218B. Such locking features 234, 236, 238 form an air-tight seal such that when the cover plate 202 is coupled to the distribution plate 204 with the collar 206 and inlet plate 220 therebetween, process gas may only enter the interior chamber 212 through the inlet plate 220 and exit the interior chamber 212 through the holes 210 in the distribution plate 204. The gas flow device 600 can include one or more 630 protrusions configured to engage one or more slits (not shown) on the inlet plate 220 to further connect the gas supply device 600 to the inlet plate 220.

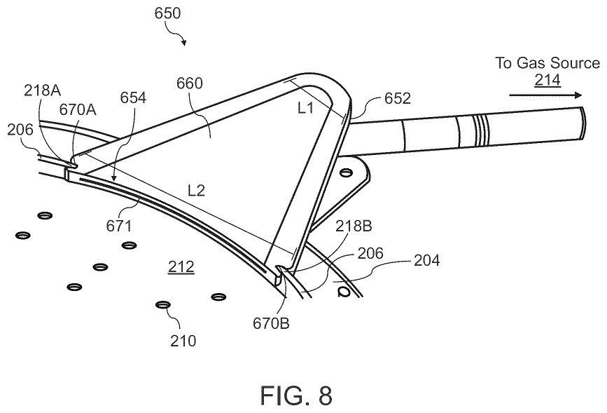

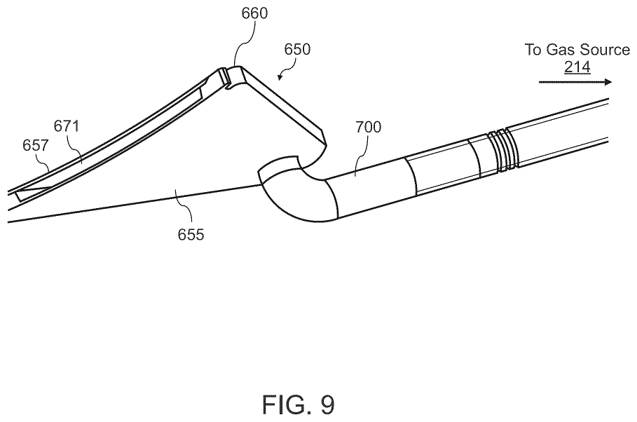

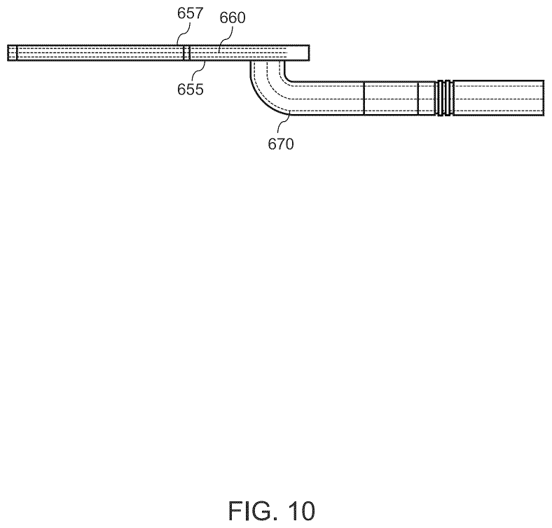

Referring now to FIGS. 8-10, in another embodiment, a gas flow device 650 is depicted that is coupled directly to the collar 206. For instance, the gas flow device 650 includes a first end 652 coupled to the gas source 214 and a second end 654 coupled to the collar 206. The second end 654 can have the same radius of curvature as the collar 206, such that coupling of the collar 206 to the gas flow device 650 makes a circle. Similar to the gas flow device 600 depicted in FIGS. 6-7, the gas flow device 650 is not tubular in nature and instead is a housing 660 having generally a top, bottom and sidewalls. Disposed along the second end 654 of the housing 660 is a single slot 671 from which process gas supplied by the process gas source 214 can enter the interior space 212. Notably, in such an embodiment, no additional distribution plate is required. The housing 610 can have a first length L1 generally along the first end 652 that is less than a second length L2 of the housing 660 disposed along the second end 654 of the gas flow device 650. The gas supply 214 can include an adapter 700 disposed between the gas flow device 650 and the gas source 214. As shown in FIGS. 9-10 the adapter 700 is configured to supply gas through a bottom 655 of the housing 660. Further, the adapter 700 is configured to supply process gas normal to an inner surface of the top 657 of the housing 660. In such embodiments, process gas entering the gas flow device 650 is dispersed within an interior of the housing 660 and can be more evenly dispersed within the housing 660 prior to exiting the housing 660 via the slot 671. Such dispersion within the housing 660 can ensure more uniformity of gas flow distribution and modify gas flow or turbulence in the process gas provided by the gas source 214.

The gas flow device 650 and collar 206, in one aspect, have locking features that couple together to form a slip-tight seal. More particularly, the gas flow device 650 has a first groove 670A for receiving the first azimuthal end 218A of the collar 206 and a similar, second channel 670B for receiving the second azimuthal end 218B of the collar 206. Such locking features 670 and 218 form an air-tight seal such that when the cover plate 202 is coupled to the distribution plate 204 with the collar 206 and gas flow device 650 therebetween, process gas may only enter the interior chamber 212 through the slot 671 of the gas flow device 650 and exit the interior chamber 212 through the holes 210 in the distribution plate 204.

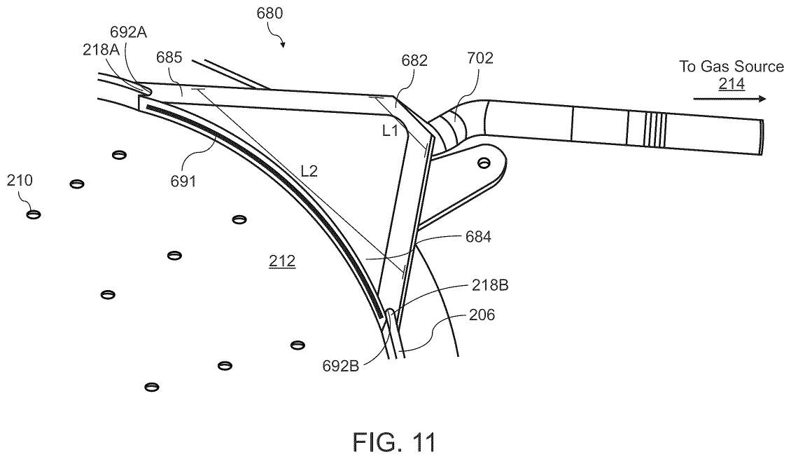

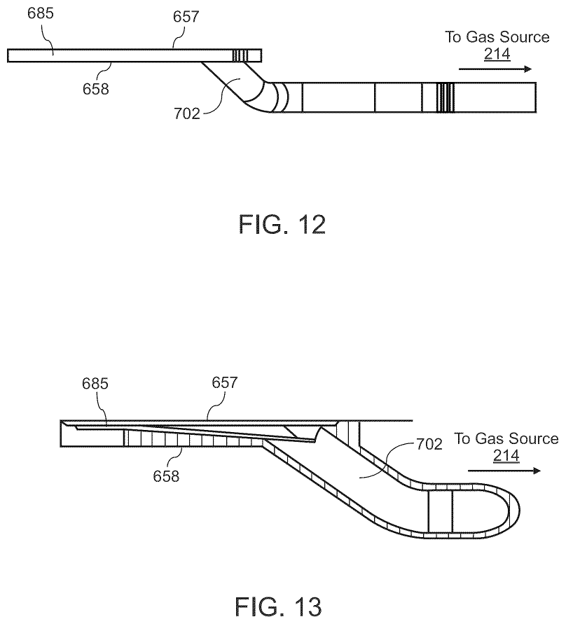

Referring now to FIGS. 11-13, in another embodiment, a gas flow device 680 is depicted that is coupled directly to the collar 206. For instance, the gas flow device 680 includes a first end 682 coupled to the gas source 214 and a second end 684 coupled to the collar 206. The second end 684 can have the same radius of curvature as the collar 206, such that coupling of the collar 206 to the gas flow device 680 makes a circle. The gas flow device 680 is not tubular in nature and instead is a housing 685 having generally a top, bottom and sidewalls. Disposed along the second end 684 of the housing 685 is a single slot 691 from which process gas supplied by the process gas source 214 can enter the interior space 212. Notably, in such an embodiment, no additional distribution plate is required. The housing 685 can have a first length L1 generally along the first end 682 that is less than a second length L2 of the housing 685 disposed along the second end 684 of the gas flow device 680. The gas supply 214 can include an adapter 702 disposed between the gas flow device 780 and the gas source 214. As depicted in FIGS. 12-13, the adapter 702 is configured to supply gas through a bottom 658 of the housing 685. Further, the adapter 702 is configured to supply process gas normal or in an angled manner to an inner surface of the top 657 of the housing 685. In such embodiments, process gas entering the gas flow device 680 is dispersed within an interior of the housing 685 and can be more evenly dispersed within the housing 685 prior to exiting the housing 685 via the slot 691. Such dispersion within the housing 685 can ensure more uniformity of gas flow distribution and modify gas flow or turbulence in the process gas provided by the gas source 214.

The gas flow device 680 and collar 206, in one aspect, have locking features that couple together to form a slip-tight seal. More particularly, the gas flow device 680 has a first groove 692A for receiving the first azimuthal end 218A of the collar 206 and a similar, second channel 692B for receiving the second azimuthal end 218B of the collar 206. Such locking features 692 and 218 form an air-tight seal such that when the cover plate 202 is coupled to the distribution plate 204 with the collar 206 and gas flow device 680 therebetween, process gas may only enter the interior chamber 212 through the slot 691 of the gas flow device 680 and exit the interior chamber 212 through the holes 210 in the distribution plate 204.

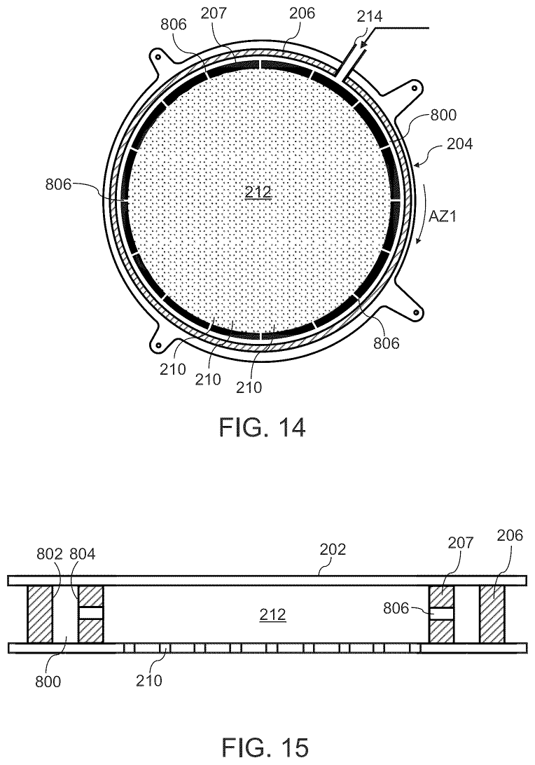

Turning now to FIGS. 14-15, in embodiments the gas delivery system 200 includes an outer collar 206 and an inner collar 207, such that the outer collar 206 and the inner collar 207 form concentric circles. Notably, the gas delivery system 200 can include one or more collars, such as a plurality of collars. A circumferential gas supply space 800 is provided between an inner surface 802 of the first collar 206 and an outer surface 804 of the second collar 207. Gas provided by the gas supply 214 first enters the circumferential gas supply space 800 and is only provided into the interior space 212 to be supplied to the distribution plate 204 by slits 806 located in the inner collar 207. The inner collar 207 can include a plurality of slits 806 spaced apart from each other in the azimuthal direction AZ1. Once through the slits 806, the gas can proceed through the holes 210 of the distribution plate 204 for use in the processing chamber 105. The cover plate 202 can be disposed over both of the inner collar 207 and the outer collar 206.

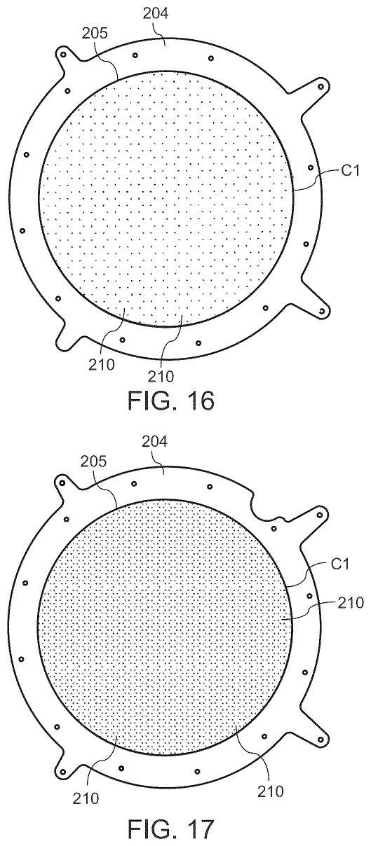

Turning generally now to FIGS. 16-20, the distribution plate 204 is separately configured to evenly disperse the process gas flowing therethrough across a workpiece. Generally, the distribution plate 204 includes holes such that at total area of the holes is from about 0.1% to about 0.9%, such as from about 0.2% to about 0.8%, such as from about 0.3% to about 0.7%, such as from about 0.4% to about 0.6% of the total area of the distribution area 205 on the distribution plate 204. For instance, the distribution area 205 generally refers to the portion of the distribution plate 204 having the pattern of holes 210 thereon. For instance, the distribution area 205 can generally be defined by the circumference of the inner wall of the innermost collar. Further, the distribution plate 204 can include a distribution area 205 defined by a circle (C1) generally having a radius of from about 275 mm to about 335 mm. The holes 210 can have the same or different cross-sectional areas. For instance, each of the holes can have the same radius or can have different radii.

Referring to FIGS. 16-17, the holes 210 can be disposed in a hexagonal pattern on the distribution plate 204 within the distribution area 205. As shown in FIG. 16, where larger diameter holes 210 are utilized, there may be fewer holes 210 spread across the distribution area 205 so as to maintain the total surface area of the holes 210 in the range described herein. However, as shown in FIG. 17, where smaller diameter holes 210 are utilized, there may be a greater number of holes 210 spread across the distribution area 205 so as to maintain the total surface area of the holes 210 in the ranges described herein. As discovered by the present inventors, control of the size, distribution, and spacing of the holes 210 as well as the total area of the holes 210 can be used to build up sufficient pressure in the gas supply system 200 to improve uniformity on the workpiece during processing.

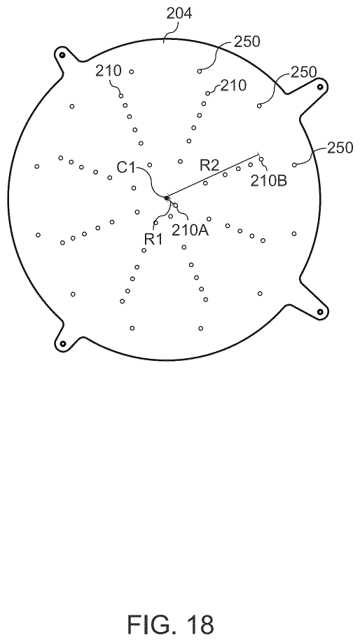

Referring specifically to FIG. 18, depicted is a gas distribution plate 204 where the holes 210 are disposed in a spiral pattern. For instance, each of the holes 210 in the distribution plate 204 is spaced apart from a center C1 of the distribution plate 204 by a different radial distance. For instance, a radially innermost, first hole 210A of the holes 210 in the distribution plate 204 is spaced apart from the center C1 by a first distance R1 and a radially outermost, second hole 210B of the holes 210 in the distribution plate 204 is spaced apart from the center C1 by a second distance R2. In one embodiment, the holes 210 in the distribution plate 204 spiral outwardly from the first hole 210A to the second hole 210B by increasingly larger radial distances. In some aspects, the holes 210 in the distribution plate 204 have a same cross-sectional area. However, in another aspect, the holes 210 extend across a same azimuthal distance. In order for the holes 210 to have a same cross-sectional area and extend across a same azimuthal distance, the holes 210 have varying shapes. Also shown are the holes 250 for receiving the fasteners as described further hereinbelow.

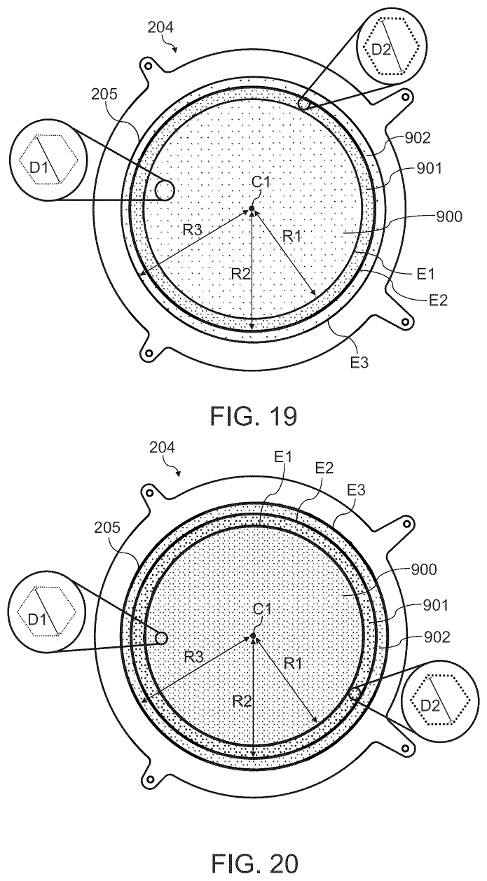

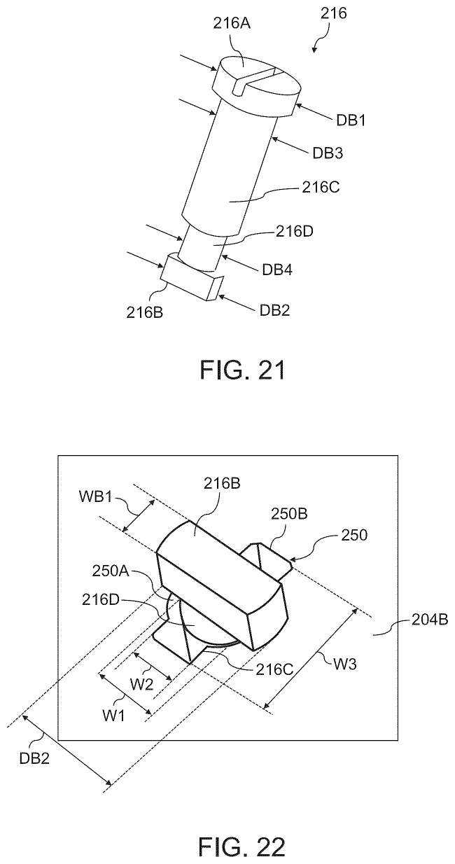

Referring now to FIGS. 20-21, the distribution plate 204 can have a distribution area 205 including one or more areas, such as a first area 900, a second area 901, a third area 902, etc. Each of the defined areas can have the same of different hole patterns. For instance, the first area 900 can have a first hole pattern and the second area 901 can include a second hole pattern. As shown, the first area 900 spans circumferentially out from a center C1 of the distribution plate 204 to a defined radius R1. The second area 901 spans from the edge E1 of the first area 900 to a second edge E2. The second edge E2 can be defined by a radius R2 from the center C1 of the distribution plate 204. Notably, the second area 901 is located circumferentially outward from the first area 900 and is closer to the edge of the distribution area 205. In embodiments, and as depicted in FIG. 20, the hole pattern of the first area 900 can be a hexagonal pattern having less densely packed holes 210 as compared to the hole pattern of the second area 901. For instance, as shown in FIG. 19, the distance D1 between the respective holes of each hexagon in the hole pattern of the first area 900 can be greater than the distance D2 between the respective holes 210 of each hexagon in the hole pattern of the second area 901. However, as illustrated in FIG. 20, in embodiments the distance D1 between the respective holes of each hexagon in the hole pattern of the first area 900 is less than the distance D2 between the respective holes of each hexagon in the hole pattern of the second area 901. In embodiments, a third area 902 also includes a hole pattern that can be the same or different from either the first or second areas 900, 901. The third area 902 is located circumferentially outward from the first area 900 and the second area 901. For instance, the third area 902 spans from the edge E2 of the second area 901 to a third edge E3. The third edge E3 can be defined by a radius R3 from the center C1 of the distribution plate 204. As depicted in FIG. 20, the third area 902 contains a random hole pattern having holes sporadically dispersed throughout the third area 924. In other embodiments, the third area 902 can include a hexagonal hole pattern or other desirable hole pattern. Notably, in certain embodiments, the total area of the holes of the third area 902 is less than the total area of the holes of the second area 901 and/or the first area 900. Further, in embodiments, the total area of the holes 210 of the first area 900 is greater than the second area 901 and/or the third area 902.

Referring generally back to FIGS. 3-4, the distribution plate 204 has a plurality of holes 250 for receiving the mechanical fasteners 216 (FIG. 3) to mount the cover plate 202 (FIG. 3) to the distribution plate 204. The holes 250 are spaced apart from the center C1 of the distribution plate 204 by a radial distance RM1, where the radial distance RM1 is greater than the second radial distance L2 at which the radially outermost hole 210B is positioned. In one embodiment, the collar 206, the inlet plate 220, and the baffle plate 226 (FIG. 4) are configured to be positioned at a radial distance between the second radial distance L2 and the radial distance RM1. In some embodiments, the holes 250 are evenly spaced apart along the azimuthal direction A1.

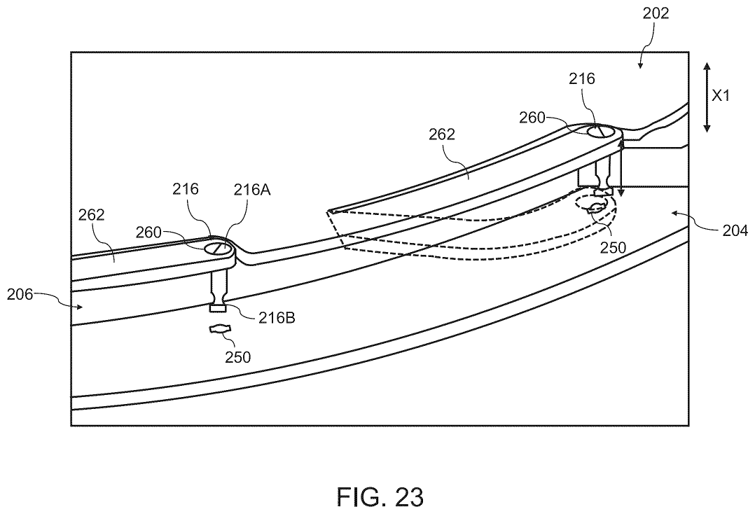

As described with reference to FIGS. 21-23, in one embodiment, each of the mechanical fasteners 216 is configured as a bayonet pin (hereafter referred to as “bayonet 216”). The bayonet 216 extends between a first portion 216A at its first end and a second portion 216B at its second end. As particularly shown in FIGS. 22 and 23, the bayonet 216 further includes a third portion 216C and optionally a fourth portion 216D, with the third portion 216C being positioned between the first portion 216A and the fourth portion 216D, and the fourth portion 216D being positioned between the third portion 216C and the second portion 216B. As shown in FIG. 21, the first portion 216A has a first diameter or width DB1, the second portion 216B has a second diameter or width DB2, the third portion 216C has a third diameter or width DB3, and the fourth portion has a fourth diameter or width DB4. The first diameter DB1 is larger than the second diameter DB2, the second diameter DB2 is larger than the third diameter DB3, and the third diameter DB3 is larger than the fourth diameter DB4.

When the bayonet 216 is in an installed or fastened position, the first portion 216A of the bayonet 216 is configured to be held within an opening or recess 260 (FIG. 23) in the cover plate 202 having a diameter that generally corresponds to the first diameter DB1, such that the first portion 216A of the bayonet 216 cannot pass completely through the cover plate 202. Further, the third portion 216C of the bayonet 216 is configured to extend at least partially through the cover plate 202 (e.g., through the portion of the cover plate 202 below the recess 260 in FIG. 23) and at least partially through the mounting hole 250 in the distribution plate 204 as shown in FIG. 22. Moreover, the fourth portion 216D of the bayonet 216, when present, extends at least partially through the mounting hole 250 in the distribution plate 204 as shown in FIG. 22. Additionally, the second portion 216B is configured to abut or rest against the lower surface 204B of the distribution plate 204.

More particularly, the mounting hole 250 has a first contour portion 250A and a second contour portion 250B. The first contour portion 250A is generally circular and has a diameter or width W1 that generally corresponds to the third diameter DB3 of the third portion 216C of the bayonet. The second contour portion 250B is generally rectangular and intersects the first contour portion 250A, where the second contour portion 250B has a width W2 in a first direction generally corresponding to a width WB1 of the second portion 216B of the bayonet 216 and a width W3 in a second direction generally corresponding to the second diameter DB2 of the second portion 216B of the bayonet 216. The bayonet 216 is configured to be inserted through the mounting hole 250 when in a first rotational position (FIG. 23), such that at least a portion of the second portion 216B of the bayonet 216 and the third and fourth portions 216C, 216D of the bayonet 216 are configured to pass through the first contour portion 250A and the remaining part of the second portion 216B of the bayonet 216 passes through the second contour portion 250B. Once the bayonet 216 is fully inserted through the mounting hole 250, such that the second portion 216B of the bayonet 216 extends past the mounting hole 250, the bayonet 216 may be rotated form the first rotational position (FIG. 23) to a second rotational position (FIG. 22), such that the bayonet 216 cannot pass back through or be removed from the mounting hole 250 without first being rotated back to the first rotational position.

As particularly shown in FIG. 22, when the cover plate 202 is positioned on the collar 206, but not fastened or coupled to the distribution plate 204, the bayonets 216 cannot extend through the holes 250. As such, the cover plate 202 includes a plurality of flexible flanges 262 extending along its outer perimeter. Each of the flanges 262 extends along a respective azimuthal section of the cover plate 202. Each flange 262 includes at least one of the recesses 260 for receiving the bayonet 216. When it is desired to couple the cover plate 202 to the distribution plate 204, a bayonet 216 may be inserted into a respective recess 260 and an external force may be applied in the axial direction X1 to bend or flex the flange into an installation position (indicated in dashed lines). The force required to bend or flex the flange into the installation position may be subsequently provided by the respective bayonet 216 when the bayonet 216 is rotated into the second rotational position (FIG. 22). Such continued force helps to seal the interior chamber 212 (FIG. 2) to prevent the process gas from exiting the chamber 212 except for through the holes 210 (FIG. 2).

It should be appreciated that the mechanical fasteners 216 may be configured as any other suitable mechanical fastener or combination of fasteners, including, but not limited to, screws, bolts, rivets, and/or the like.

It should further be appreciated that the gas delivery system 200 is mainly or completely comprised of quartz material. For instance, in one embodiment, at least the cover plate 202, the distribution plate 204, the collar 206, the inlet plate 220, the baffle plate 226, the inlet tubes 230, gas flow devices 600, 650, 680, and adapters 700, 702, each comprise quartz material. Further, in some embodiments, the fasteners 216 are comprised of quartz material. The components of the gas delivery system 200 comprise of quartz may be fire polished such that the number of particles generated by the gas delivery system 200 during an anneal process that may contaminate the workpiece is reduced.

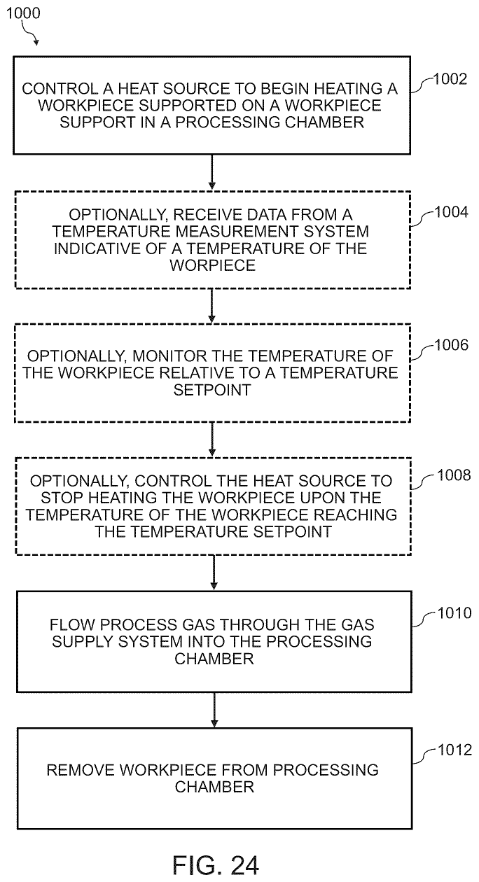

FIG. 24 depicts a flow diagram of an example method (1000) according to example embodiments of the present disclosure. The method (1000) will be discussed with reference to the thermal processing system 100 of FIG. 1 by way of example. The method (1000) can be implemented in any suitable plasma processing apparatus. FIG. 24 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (1002), the method 1000 can include controlling a heat source to begin heating a workpiece supported on a workpiece support within a processing chamber. For instance, a controller 190 of the thermal processing system 100 can control a heat source(s) 150 to begin heating (i.e., emitting light towards) a workpiece 120 supported on a workpiece support 130, 132 within a processing chamber 105.

Optionally, at (1004), the method 500 can further include receiving data from a temperature measurement system indicative of a temperature of a workpiece during a spike anneal process. For instance, the thermal processing system 100 can include one or more temperature sensors 180 which can generate and communicate data indicative of a temperature of the workpiece 120.

Optionally, at (1006), the method 500 can include monitoring the temperature of the workpiece relative to a temperature setpoint. For instance, a controller 190 of the thermal processing system 100 can access data indicative of a temperature setpoint. The temperature setpoint can be within about 20% of a peak temperature of a heating profile associated with the spike anneal heating profile.

Optionally, at (1008), the method 500 can include controlling the heat source to stop heating the workpiece based at least in part on the temperature of the workpiece reaching the temperature setpoint. For instance, when a temperature of the workpiece 120 reaches or exceeds the temperature setpoint, the controller 190 can control the heat source(s) 150 to stop heating (i.e., emitting light towards) the workpiece 120.

Additionally, at (1010), the method can include controlling a gas delivery system to begin flowing a process gas over the workpiece using the gas supply system 200 as depicted herein. For instance, the process gas can be supplied by the gas supply 214 and provided to the gas supply system 200 having a gas distribution plate 204 as depicted herein. Further, process gas can only be supplied to the interior of the processing chamber 105 from the gas supply system 200 and, more specifically, through the holes 210 located in the gas distribution plate 204.

At, (1012), the method can include stopping the flow of process gas and/or stopping processing of the workpiece, and removing the workpiece from the processing chamber 105.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A gas delivery system for a thermal processing apparatus, comprising:
a cover plate;
a distribution plate extending axially between a first surface and a second surface, the first and second surfaces extending perpendicular to the axial direction, the distribution plate having a distribution area comprising plurality of holes extending axially therethrough;
one or more collars coupled axially between the cover plate and the distribution plate, the collar, the cover plate, and the distribution plate together defining an interior chamber; and
a gas supply coupled to the collar to provide process gas from a gas source to the interior chamber,
wherein a total area of the holes is from about 0.1% to about 0.9% of a total area of the distribution area on the distribution plate.

2. The system of claim 1, wherein the gas supply comprises an inlet plate coupled to and extending along an azimuthal direction between first and second ends of the collar spaced apart by a gap distance, the inlet plate comprising a plurality of inlet openings spaced apart along the azimuthal direction.

3. The system of claim 2, wherein the gas supply further comprises a plurality of inlet tubes, each of the plurality of inlet tubes connecting a respective one of the plurality of inlet openings to the gas source.

4. The system of claim 3, wherein the gas supply further comprises a baffle plate extending along at least part of the gap distance and spaced radially inwardly from the inlet plate, the baffle plate having a plurality of diffusing openings.

5. The system of claim 4, wherein the plurality of diffusing openings of the baffle plate and the plurality of inlet openings of the inlet plate are spaced apart along the azimuthal direction, and
wherein the plurality of diffusing openings of the baffle plate and the plurality of inlet openings of the inlet plate alternate along the azimuthal direction.

6. The system of claim 1, wherein the gas supply comprises an inlet plate coupled to and extending along an azimuthal direction between first and second ends of the collar spaced apart by a gap distance, the inlet plate comprising a plurality of inlet openings spaced apart along the azimuthal direction.

7. The system of claim 1, wherein the gas supply comprises a gas flow device having a first end coupled to the gas supply and a second end coupled to an inlet plate.

8. The system of claim 7, wherein the gas flow device comprises a housing, the housing having a first end coupled to the gas supply and a second end coupled to the collar, wherein the first end has a first height that is greater than a second height disposed at the second end.

9. The system of claim 7, wherein the gas flow device comprises a slit in an azimuthal direction configured to provide process gas to an interior chamber.

10. The system of claim 8, wherein the gas supply is configured to supply gas generally parallel to a top and a bottom of the housing.

11. The system of claim 8, wherein the first end of the housing has a first length that is less than a second length of the housing disposed at the second end.

12. The system of claim 1, wherein the gas supply comprises a gas flow device having a first end coupled to the gas supply and a second end coupled to the collar.

13. The system of claim 12, wherein the gas flow device comprises a housing, the housing having a first height at the first end and a second height at the second end, wherein the first height is greater than the second height.

14. The system of claim 13, wherein the gas supply comprises an adapter disposed between the gas source and the housing, the adapter configured to provide process gas through a bottom of the housing.

15. The system of claim 14, wherein the adapter is configured to provide process gas normal to an inner surface of a top of the housing.

16. The system of claim 1, wherein the one or more collars comprise an outer collar and an inner collar, defining a circumferential gas supply space between the outer collar and the inner collar, wherein the gas supply is configured to supply process gas to the circumferential gas supply space.

17. The system of claim 16, wherein the inner collar comprises a plurality of slits configured to provide the process gas to the interior chamber.

18. The system of claim 16, wherein the distribution area is located within a circumference of the inner collar.

19. A thermal processing system for performing rapid thermal processing of semiconductor workpieces, comprising:
a processing chamber;
a workpiece support configured to support a workpiece within the processing chamber;
a heat source configured to heat the workpiece;
a temperature measurement system configured to generate data indicative of a temperature of the workpiece;
a gas delivery system configured to flow a process gas over the workpiece supported on the workpiece support, the gas delivery system comprising:
a cover plate;
a distribution plate extending axially between a first surface and a second surface, the first and second surfaces extending perpendicular to the axial direction, the distribution plate having a distribution area comprising plurality of holes extending axially therethrough;
one or more collars coupled axially between the cover plate and the distribution plate, the collar, the cover plate, and the distribution plate together defining an interior chamber; and
a gas supply coupled to the collar to provide process gas from a gas source to the interior chamber,
wherein a total area of the holes is from about 0.1% to about 0.9% of a total area of the distribution area on the distribution plate.

20. A method for performing a thermal process, comprising:
controlling, by one or more controllers, a heat source to begin heating a workpiece supported on a workpiece support in a processing chamber;
optionally, receiving, by the one or more control devices, data from a temperature measurement system indicative of a temperature of the workpiece;
optionally, monitoring, by the one or more control devices, the temperature of the workpiece relative to a temperature setpoint;
controlling, by the one or more controllers, a gas delivery system to supply a process gas to the processing chamber, the gas delivery system comprising:
a cover plate;
a distribution plate extending axially between a first surface and a second surface, the first and second surfaces extending perpendicular to the axial direction, the distribution plate having a distribution area comprising plurality of holes extending axially therethrough;
one or more collars coupled axially between the cover plate and the distribution plate, the collar, the cover plate, and the distribution plate together defining an interior chamber; and
a gas supply coupled to the collar to provide process gas from a gas source to the interior chamber,
wherein a total area of the holes is from about 0.1% to about 0.9% of a total area of the distribution area on the distribution plate; and
after the thermal process is complete, removing the workpiece from the processing chamber.
